(19) United States
(12) Patent Application Publication
(10) Pub. No.: US 2025/0158152 A1
(43) Pub. Date: May 15, 2025

(54) SYSTEM AND METHOD FOR CONTROLLING COOLING ASSEMBLY OF BATTERY SYSTEM

(71) Applicant: Caterpillar Inc., Peoria, IL (US)

(72) Inventor: Bradley Read, Lafayette, IN (US)

(73) Assignee: Caterpillar Inc., Peoria, IL (US)

(21) Appl. No.: 18/505,168

(22) Filed: Nov. 9, 2023

(51) Int. Cl. H01M 10/637; G01R 31/385; G01R 33/07; H01M 10/613

(52) U.S. Cl. CPC H01M 10/637; G01R 31/385; G01R 33/072; H01M 10/613

(57) ABSTRACT

A system for controlling a cooling assembly of a battery system includes a sensor configured to indicate an increase in a loading on the battery system. The system also includes a controller communicably coupled with the sensor. The controller is configured to receive the indication of the increase in the loading on the battery system. The controller is also configured to generate a control signal to activate the cooling assembly to cool one or more components of the battery system based on the increase in the loading on the battery system.

### TECHNICAL FIELD

The present disclosure relates to a battery system, a system for controlling a cooling assembly of the battery system, and a method for controlling the cooling assembly of the battery system.

### BACKGROUND

A battery system may be used in different applications, such as, in an energy storage system, a work machine, and the like to provide/store operating power.

Generally, under heavy load conditions, an increase in current demand from the battery system may lead to heating of the battery system. If the temperature of the battery system rises beyond a threshold temperature value, the battery system may overheat, which may lead to a failure of the battery system. Generally, a cooling system of the battery system is configured to monitor a rise in temperature of the battery system to activate the cooling system. Further, under heavy load conditions, rise in the temperature of the battery system lags increase in current demands. This phenomenon may lead to considerable increase in the temperature of the battery system before the cooling system is activated and takes time to catch up.

CN113212186 discloses a battery replacing system for an electric loader and the loader. The battery replacing system is used for being detachably arranged on the loader and comprises a battery pack, a battery controller, a cooling module, a power distribution module, a connecting interface and a charging interface; the cooling module is connected with the power distribution module, is also in communication connection with the battery controller and is used for cooling the battery pack; the battery pack is connected with the charging interface and the connecting interface through the power distribution module; the battery controller is connected with the battery pack and the power distribution module, and is in communication connection with the connection interface and the charging interface; and the connection interface is used for being connected with the loader, and the battery pack supplies power to the loader through the connection interface and performs charging through the charging interface. According to the scheme, all functional modules are designed into an integrated battery replacing system, and the battery replacing system is connected with the loader through the connecting interface, so that the battery replacing system is convenient to mount and dismount. In addition, when the electric quantity is insufficient, a standby battery replacing system can be replaced to continuously provide electric energy for the loader, and the working efficiency of the loader is improved.

### SUMMARY OF THE DISCLOSURE

In an aspect of the present disclosure, a system for controlling a cooling assembly of a battery system is provided. The system includes a sensor configured to indicate an increase in a loading on the battery system. The system also includes a controller communicably coupled with the sensor. The controller is configured to receive the indication of the increase in the loading on the battery system. The controller is also configured to generate a control signal to activate the cooling assembly to cool one or more components of the battery system based on the increase in the loading on the battery system.

In another aspect of the present disclosure, a battery system is provided. The battery system includes one or more battery modules. The battery system also includes a cooling assembly for the one or more battery modules. The battery system further includes a system for controlling the cooling assembly. The system includes a sensor configured to indicate an increase in a loading on the battery system. The system also includes a controller communicably coupled with the sensor. The controller is configured to receive the indication of the increase in the loading on the battery system. The controller is also configured to generate a control signal to activate the cooling assembly to cool one or more components of the battery system based on the increase in the loading on the battery system.

In yet another aspect of the present disclosure, a method for controlling a cooling assembly of a battery system is provided. The method includes receiving, from a sensor, an indication of an increase in a loading on the battery system. The method also includes receiving, by a controller, the indication of the increase in the loading on the battery system. The method further includes generating, by the controller, a control signal to activate the cooling assembly to cool one or more components of the battery system based on the increase in the loading on the battery system.

Other features and aspects of this disclosure will be apparent from the following description and the accompanying drawings.

### BRIEF DESCRIPTION OF THE DRAWINGS

FIG. 1 is a schematic side view of an exemplary battery energy storage system;

FIG. 2 is a block diagram illustrating a battery system associated with the battery energy storage system of FIG. 1 and a system for controlling a cooling assembly of the battery system, according to an example of the present disclosure;

FIG. 3 is a plot depicting an impact of a C-rating of the battery system on a response time of the system shown in FIG. 2, according to an example of the present disclosure;

FIG. 4 is a flowchart of a method for controlling the cooling assembly of the battery system of FIG. 2, according to an example of the present disclosure.

### DETAILED DESCRIPTION

Wherever possible, the same reference numbers will be used throughout the drawings to refer to the same or like parts.

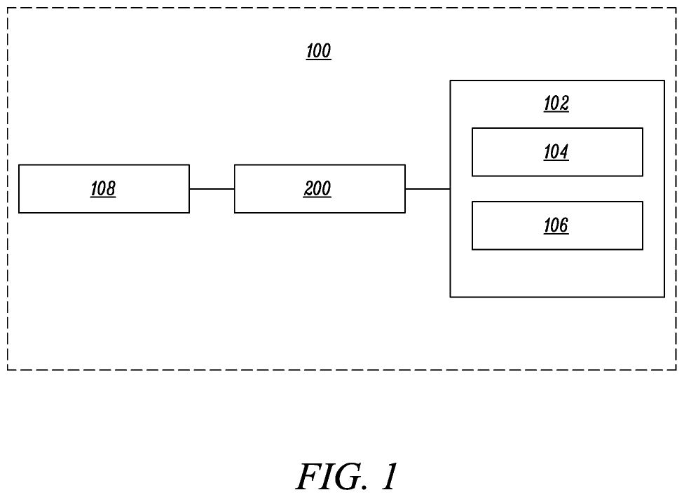

Referring to FIG. 1, a block diagram of an exemplary battery energy storage system 100 is illustrated. The battery energy storage system 100 may include any known energy storage system that employs batteries. The battery energy storage system 100 may be capable of storing surplus power from any combination of sources, such as, diesel, natural gas, renewable wind or solar, biogas, hydrogen, or blends of hydrogen. In some examples, the battery energy storage system 100 may operate as a back-up power source for a wide range of applications.

The battery energy storage system 100 includes a battery system 200 and a power conversion system 102. The power conversion system 102 may include an inverter 104 and a converter 106. The battery energy storage system 100 may further include a controller 108 and/or other power electronic components (not shown), such as, switches. The controller 108 may sense, determine, and/or store various characteristics of the battery energy storage system 100. Such characteristics of the battery energy storage system 100 may include, among others, a current state of charge, a current energy, a state of charge minimum threshold, a state of charge maximum threshold, and a discharge limit of the battery energy storage system 100, without any limitations. In some examples, the battery energy storage system 100 may be a part of a microgrid that may send and receive power. The microgrids may include a plurality of different energy storage systems (similar to the battery energy storage system 100), fuel cells, etc.

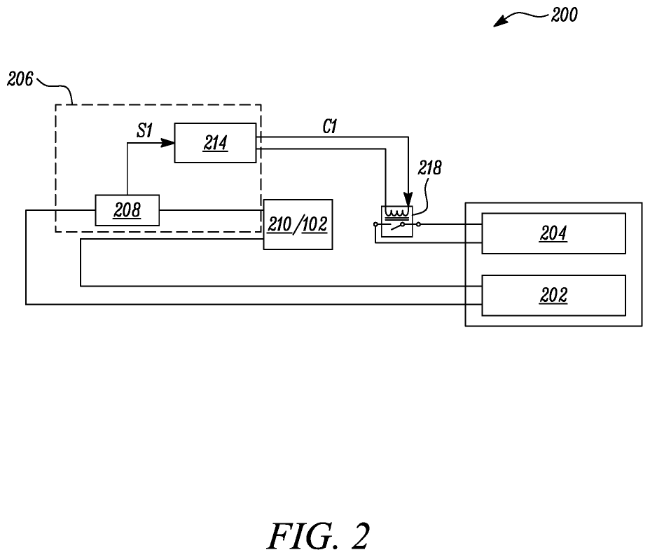

Referring to FIG. 2, a block diagram of the battery system 200 associated with the battery energy storage system 100 of FIG. 1 is illustrated. The battery system 200 includes one or more battery modules 202. The battery modules 202 may provide a desired amount of power output and voltage output. In some examples, each battery module 202 may embody a high-voltage battery module and may include one or more battery cells (not shown), such as, lithium titanate battery cells. The battery cells store electrical power and distribute the stored electrical power at the desired amount of power output and voltage output. It should be noted that the power distribution and power storage characteristics of the battery system 200 may be defined at least in part on the configurations of the one or more battery cells included in the battery modules 202. In other examples, the battery module 202 may embody any other type of battery technology, such as, a lead-acid battery technology, a nickel metal hydride battery technology, and the like.

The battery system 200 also includes a cooling assembly 204 for the battery system 200. For example, the cooling assembly 204 may maintain a temperature of the battery modules 202 within desired limits. In some examples, the cooling assembly 204 may include a liquid-cooled assembly that uses liquid to cool the battery system 200. For example, the liquid-cooled assembly may include a liquid cooling jacket (not shown) to cool the battery system 200. The cooling jacket may include one or more cooling passages that receive a coolant to cool the battery system 200. Alternatively, the cooling assembly 204 may include an air-cooled assembly that may include a fan that generates an airflow to cool the battery system 200.

The battery system 200 further includes a system 206 for controlling the cooling assembly 204 of the battery system 200. Although the system 206 is shown in association with the battery energy storage system 100, the system 206 described herein may be associated with any battery system that may be usable for different applications. The system 206 includes a sensor 208. The sensor 208 is disposed between the battery system 200, and a load 210 that receives an electric power supply from the battery system 200 or a power conversion system 102. It should be noted that the load 210 may include any end device that uses the power supply supplied by the battery energy storage system 100.

The sensor 208 indicates an increase in a loading on the battery system 200. Specifically, the sensor 208 generates a current signal S1 indicative of a current flowing through the battery system 200 to meet the loading on the battery system 200. The sensor 208 includes a hall effect current sensor. Specifically, the sensor 208 is a direct current hall effect sensor. Alternatively, the sensor 208 may include any other type of sensor that generates the current signal S1.

The system 206 also includes a controller 214 communicably coupled with the sensor 208. The controller 214 includes one or more memories to store information pertaining to a threshold current capacity value of the battery system 200, a threshold current surge rate for the battery system 200, a C-rating of the battery system 200, and the like. The memories may include any means of storing information, including a hard disk, an optical disk, a floppy disk, ROM (read only memory), RAM (random access memory), PROM (programmable ROM), EEPROM (electrically erasable PROM), and/or other computer-readable memory media.

The controller 214 also includes one or more processors communicably coupled to the one or more memories. It should be noted that the one or more processors may embody a single microprocessor or multiple microprocessors for receiving various input signals and generating output signals. Numerous commercially available microprocessors may perform the functions of the one or more processors. Each processor may further include a general processor, a central processing unit, an application specific integrated circuit (ASIC), a digital signal processor, a field programmable gate array (FPGA), a digital circuit, an analog circuit, a microcontroller, any other type of processor, or any combination thereof. Each processor may include one or more components that may be operable to execute computer executable instructions or computer code that may be stored and retrieved from the one or more memories.

The controller 214 receives the indication of the increase in the loading on the battery system 200. Specifically, the controller 214 receives the current signal S1 generated by the sensor 208. The controller 214 generates a control signal C1 to activate the cooling assembly 204 to cool one or more components of the battery system 200 based on the increase in the loading on the battery system 200. For example, the control signal C1 generated by the controller 214 may activate the cooling assembly 204 to cool the battery modules 202. Based on the activation of the cooling assembly 204, a coolant may be directed towards the battery system 200 for cooling the components of the battery system 200. Further, the cooling assembly 204 includes an output relay 218 communicably coupled to the controller 214. The output relay 218 may be a switch that activates the cooling assembly 204 based on receipt of the control signal C1 generated by the controller 214, in order to cool the battery system 200.

In one example, to generate the control signal C1, the controller 214 compares a value of the current signal S1 received from the sensor 208 with a threshold current capacity value of the battery system 200. It should be noted that the threshold current capacity value is a threshold value beyond which the battery system 200 may require cooling to avoid excessive temperature rise or overheating of the battery system 200. Further, the threshold current capacity value may be stored in the memories associated with the controller 214 and can be retrieved from the memories by the controller 214 for comparison.

Further, the controller 214 activates the cooling assembly 204 if the value of the current signal S1 is greater than the threshold current capacity value of the battery system 200. Particularly, the controller 214 generates the control signal C1 to activate the cooling assembly 204 if the value of the current signal S1 is greater than the threshold current capacity value of the battery system 200.

In another example, to generate the control signal C1, the controller 214 monitors a surge rate of the current flowing through the battery system 200, based on the value of the current signal S1 received from the sensor 208. The controller 214 compares the surge rate of the current flowing through the battery system 200 with a threshold current surge rate. It should be noted that the threshold current surge rate is a threshold rate of increase in current beyond which the battery system 200 may require cooling to avoid excessive temperature rise or overheating of the battery system 200. Further, the threshold current surge rate may be stored in the memories associated with the controller 214 and can be retrieved from the memories by the controller 214 for comparison.

Further, the controller 214 activates the cooling assembly 204 if the surge rate of the current flowing through the battery system 200 is greater than the threshold current surge rate. Particularly, the controller 214 generates the control signal C1 to activate the cooling assembly 204 if the surge rate of the current flowing through the battery system 200 is greater than the threshold current surge rate.

Furthermore, a response time of the controller 214 between the receipt of the current signal S1 and the generation of the control signal C1 is based on a C-rating of the battery system 200. It should be noted that the C-rating is defined as a rate of time required to charge or discharge the battery system 200.

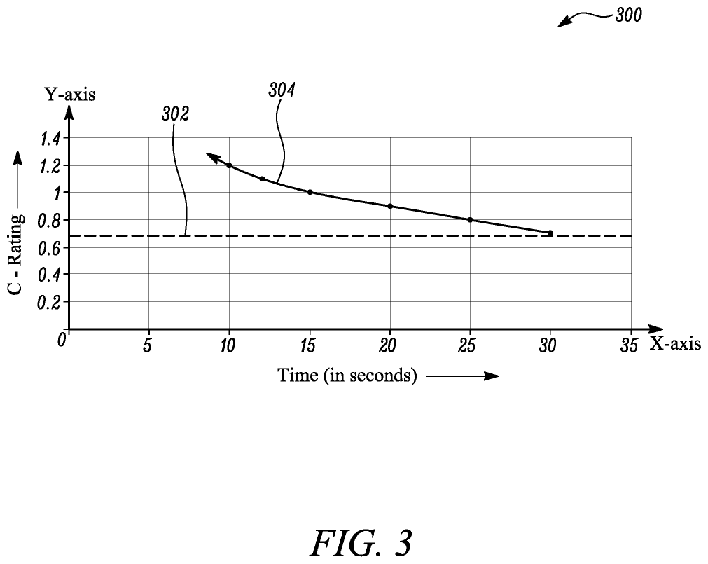

FIG. 3 illustrates a plot 300 depicting an impact of the C-rating of the battery systems (such as the battery system 200 shown in FIG. 2) on the response time of the system 206. Various values for response time (in seconds) are marked on the X-axis and various values for C-rating for battery systems are marked on the Y-axis. As shown in FIG. 3, a line 302 is a threshold line below which the controller 214 does not generate the control signal C1 (see FIG. 2). Specifically, if the C-rating of the battery system 200 is approximately below 0.7, the controller 214 does not generate the control signal C1. The plot 300 also illustrates a curve 304 depicting response time values corresponding to different C-rating values. As observed from FIG. 3, only if the C-rating of the battery system is approximately above 0.7, the controller 214 generates the control signal C1. Further, the response time decreases as the C-rating increases. Particularly, if a particular battery system has a C-rating of 0.8, the response time will be 25 seconds, if a particular battery system has a C-rating of 1, the response time will be 15 seconds, and so on.

It is to be understood that individual features shown or described for one embodiment may be combined with individual features shown or described for another embodiment. The above described implementation does not in any way limit the scope of the present disclosure. Therefore, it is to be understood although some features are shown or described to illustrate the use of the present disclosure in the context of functional segments, such features may be omitted from the scope of the present disclosure without departing from the spirit of the present disclosure as defined in the appended claims.

### INDUSTRIAL APPLICABILITY

The present disclosure is related to the system 206. The system 206 includes the sensor 208 that indicates the increase in the loading on the battery system 200. The system 206 also includes the controller 214 that receives the indication of the increase in the present loading on the battery system 200. Further, based on the increase in the loading on the battery system 200, the controller 214 generates the control signal C1 to activate the cooling assembly 204, in order to mitigate excessive temperature rise or overheating of the components of the battery system 200.

Since in case of heavy load conditions, an increase in current demand may increase the loading on the battery system 200. The system 206 accordingly activates the cooling assembly 204 and may prevent rise in temperature of the battery system 200 beyond a threshold temperature value. Activating the cooling assembly 204 based on the loading on the battery system 200 may prevent overheating of the battery system 200, thereby preventing bulging, swelling, warping, or even failure of the battery system 200.

Therefore, as compared to conventional battery systems, the system 206 of the present disclosure may prevent damage to internal components of the battery system 200 as well as the components disposed around the battery system 200, thereby reducing downtime and costs associated with servicing/replacement of the battery system 200. Further, the system 206 may be cost effective as the system 206 does not employ complicated/costly components, and may be retrofitted on existing energy storage systems.

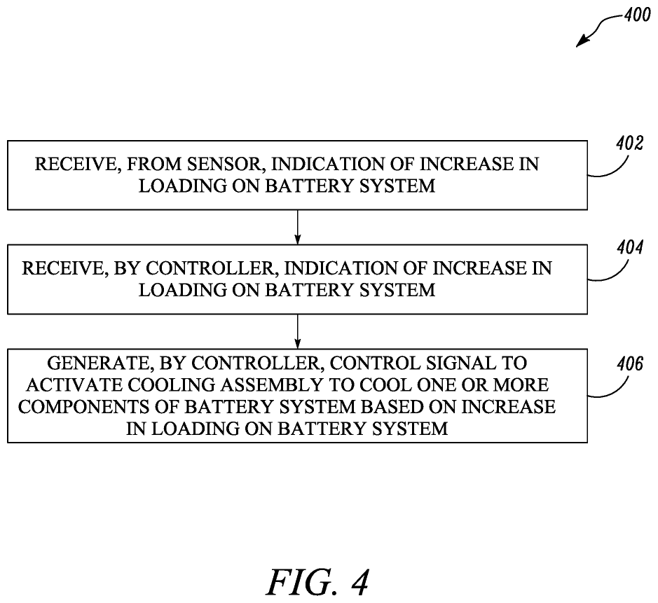

Referring to FIG. 4, a flowchart of a method 400 for controlling the cooling assembly 204 of the battery system 200 of FIG. 2 is illustrated.

At step 402, the indication of the increase in the loading on the battery system 200 is received from the sensor 208. The method 400 includes a step of disposing the sensor 208 between the battery system 200, and the load 210 that receives the electric power supply from the battery system 200 or the power conversion system 211. The method 400 also includes a step at which the sensor 208 generates the current signal S1 indicative of the current flowing through the battery system 200 to meet the loading on the battery system 200.

At step 404, the indication of the increase in the loading on the battery system 200 is received by the controller 214.

At step 406, the control signal C1 is generated by the controller 214 to activate the cooling assembly 204 to cool the one or more components of the battery system 200 based on the increase in the loading on the battery system 200. Further, the response time of the controller 214 between the receipt of the current signal S1 and the generation of the control signal C1 is based on the C-rating of the battery system 200.

The method 400 includes a step at which the controller 214 compares the value of the current signal S1 received from the sensor 208 with the threshold current capacity value of the battery system 200. The method 400 also includes a step at which the controller 214 activates the cooling assembly 204, if the value of the current signal S1 is greater than the threshold current capacity value of the battery system 200.

The method 400 includes a step at which the controller 214 monitors the surge rate of the current flowing through the battery system 200 based on the value of the current signal S1 received from the sensor 208. The method 400 also includes a step at which the controller 214 compares the surge rate of the current flowing through the battery system 200 with the threshold current surge rate. The method 400 further includes a step at which the controller 214 activates the cooling assembly 204, if the surge rate of the current flowing through the battery system 200 is greater than the threshold current surge rate.

While aspects of the present disclosure have been particularly shown and described with reference to the embodiments above, it will be understood by those skilled in the art that various additional embodiments may be contemplated by the modification of the disclosed machine, systems and methods without departing from the spirit and scope of the disclosure. Such embodiments should be understood to fall within the scope of the present disclosure as determined based upon the claims and any equivalents thereof.

What is claimed is:

1. A system for controlling a cooling assembly of a battery system, the system comprising:
a sensor configured to indicate an increase in a loading on the battery system; and
a controller communicably coupled with the sensor, wherein the controller is configured to:
receive the indication of the increase in the loading on the battery system; and
generate a control signal to activate the cooling assembly to cool one or more components of the battery system based on the increase in the loading on the battery system.

2. The system of claim 1, wherein the sensor is configured to generate a current signal indicative of a current flowing through the battery system to meet the loading on the battery system.

3. The system of claim 2, wherein the controller is further configured to:
compare a value of the current signal received from the sensor with a threshold current capacity value of the battery system; and
activate the cooling assembly if the value of the current signal is greater than the threshold current capacity value of the battery system.

4. The system of claim 2, wherein the controller is further configured to:
monitor a surge rate of the current flowing through the battery system, based on a value of the current signal received from the sensor;
compare the surge rate of the current flowing through the battery system with a threshold current surge rate; and
activate the cooling assembly if the surge rate of the current flowing through the battery system is greater than the threshold current surge rate.

5. The system of claim 2, wherein a response time of the controller between the receipt of the current signal and the generation of the control signal is based on a C-rating of the battery system.

6. The system of claim 1, wherein the sensor includes a hall effect current sensor.

7. The system of claim 1, wherein the sensor is disposed between the battery system and at least one of a load that receives an electric power supply from the battery system and a power conversion system.

8. A battery system comprising:
one or more battery modules;
a cooling assembly for the battery system; and
a system for controlling the cooling assembly, the system including:
a sensor configured to indicate an increase in a loading on the battery system; and
a controller communicably coupled with the sensor, wherein the controller is configured to:
receive the indication of the increase in the loading on the battery system; and
generate a control signal to activate the cooling assembly to cool one or more components of the battery system based on the increase in the loading on the battery system.

9. The battery system of claim 8, wherein the sensor is configured to generate a current signal indicative of a current flowing through the battery system to meet the loading on the battery system.

10. The battery system of claim 9, wherein the controller is further configured to:
compare a value of the current signal received from the sensor with a threshold current capacity value of the battery system; and
activate the cooling assembly if the value of the current signal is greater than the threshold current capacity value of the battery system.

11. The battery system of claim 9, wherein the controller is further configured to:
monitor a surge rate of the current flowing through the battery system, based on a value of the current signal received from the sensor;
compare the surge rate of the current flowing through the battery system with a threshold current surge rate; and
activate the cooling assembly if the surge rate of the current flowing through the battery system is greater than the threshold current surge rate.

12. The battery system of claim 9, wherein a response time of the controller between the receipt of the current signal and the generation of the control signal is based on a C-rating of the battery system.

13. The battery system of claim 8, wherein the sensor includes a hall effect current sensor.

14. The battery system of claim 8, wherein the sensor is disposed between the battery system and at least one of a load that receives an electric power supply from the battery system and a power conversion system.

15. A method for controlling a cooling assembly of a battery system, the method comprising:
receiving, from a sensor, an indication of an increase in a loading on the battery system;
receiving, by a controller, the indication of the increase in the loading on the battery system; and
generating, by the controller, a control signal to activate the cooling assembly to cool one or more components of the battery system based on the increase in the loading on the battery system.

16. The method of claim 15 further comprising generating, by the sensor, a current signal indicative of a current flowing through the battery system to meet the loading on the battery system.

17. The method of claim 16 further comprising:
comparing, by the controller, a value of the current signal received from the sensor with a threshold current capacity value of the battery system; and
activating, by the controller, the cooling assembly if the value of the current signal is greater than the threshold current capacity value of the battery system.

18. The method of claim 16 further comprising:
monitoring, by the controller, a surge rate of the current flowing through the battery system, based on a value of the current signal received from the sensor;
comparing, by the controller, the surge rate of the current flowing through the battery system with a threshold current surge rate; and
activating, by the controller, the cooling assembly if the surge rate of the current flowing through the battery system is greater than the threshold current surge rate.

19. The method of claim 16, wherein a response time of the controller between the receipt of the current signal and the generation of the control signal is based on a C-rating of the battery system.

20. The method of claim 15, further comprising disposing the sensor between the battery system and at least one of a load that receives an electric power supply from the battery system and a power conversion system.
